(19) United States
(12) Patent Application Publication
(10) Pub. No.: US 2026/0291478 A1
(43) Pub. Date: Sep. 24, 2026

(54) Clock output apparatus having phase detection and calibration mechanism

(71) Applicant: REALTEK SEMICONDUCTOR CORPORATION, Hsinchu (TW)

(72) Inventors: PING-YUAN DENG, Hsinchu (TW); KA-UN CHAN, Hsinchu (TW)

(21) Appl. No.: 19/558,563

(22) Filed: Mar. 6, 2026

(30) Foreign Application Priority Data
Mar. 21, 2025 (TW) 114110864

(51) Int. Cl. H03K 5/13; H03F 3/45

(52) U.S. Cl. CPC H03K 5/13; H03F 3/45264

(57) ABSTRACT

A clock output apparatus is provided. A clock output circuit generates output clock signals. A phase detection circuit includes a cross-coupled pair circuit, a differential input pair circuit and a determining circuit. The cross-coupled pair circuit is coupled between a power voltage and two output terminals. The differential input pair circuit is coupled between the output terminals and a ground terminal and has two input terminals to receive the output clock signals. The output terminals generate output signals both within and both beyond a predetermined range respectively when the phases of the output clock signals are the same and opposite such that the determining circuit generates a phase determining result. The clock output circuit performs a phase calibration process when being operated from a second mode to a first mode and when the phase determining result indicates that the output clock signals does not have a predetermined phase relation.

### BACKGROUND OF THE INVENTION

### 1. Field of the Invention

The present invention relates to a clock output apparatus having a phase detection and calibration mechanism.

### 2. Description of Related Art

In a multi-input multi-output (MIMO) communication system, different wireless receiver terminals (RX) may operate at the same frequency to receive a signal from the same wireless signal delivering terminal and may operate at different frequencies to receive signals from different wireless signal delivering terminals.

In the operation described above, the wireless receiver terminal may receive clock signals of different frequencies from different clock sources to operate accordingly. However, when the wireless receiver terminal switches between different clock sources, a phase variation may occur, in which the phase variation may result in an error to the signal receiving and the signal processing.

### SUMMARY OF THE INVENTION

In consideration of the problem of the prior art, an object of the present invention is to supply a clock output apparatus having a phase detection and calibration mechanism.

The present invention discloses a clock output apparatus having a phase detection and calibration mechanism that includes a clock output circuit and a phase detection circuit. The clock output circuit is configured to operate in a first mode and a second mode in turn to generate a pair of output clock signals, wherein the pair of output clock signals have a predetermined phase relation in the first mode. The phase detection circuit includes a cross-coupled pair circuit, a differential input pair circuit and a determining circuit. The cross-coupled pair circuit is electrically coupled between a power voltage and two output terminals. The determining circuit is electrically coupled between the two output terminals and a ground voltage and having two input terminals configured to receive the pair of output clock signals, wherein the cross-coupled pair circuit and the differential input pair circuit operate together to generate two output signals at the two output terminals each having a level in a predetermined range around a center that is a half of the power voltage when the output clock signals are in phase and generate the two output signals at the two output terminals each having the level that is not in the predetermined range when the output clock signals are out of phase. The determining circuit is configured to receive at least one of the two output signals from the two output terminals to generate a phase determining result. The clock output circuit performs a phase calibration process when the clock output circuit returns to the first mode from the second mode and the phase determining result indicates that the pair of output clock signals do not have the predetermined phase relation, so as to control the pair of output clock signals to have the predetermined phase relation.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1 illustrates a circuit diagram of a clock output apparatus having a phase detection and calibration mechanism according to an embodiment of the present invention.

FIG. 2A and FIG. 2B illustrate block diagrams of the clock output circuit according to an embodiment of the present invention.

FIG. 3 illustrates a block diagram of the phase detection circuit according to an embodiment of the present invention.

FIG. 4A and FIG. 4B illustrate waveform diagrams of the first output clock signal, the second output clock signal, the first output signal and the second output signal according to an embodiment of the present invention.

FIG. 5 illustrates a block diagram of the phase detection circuit according to another embodiment of the present invention.

FIG. 6 illustrates a block diagram of the clock output circuit according to another embodiment of the present invention.

### DETAILED DESCRIPTION OF THE PREFERRED EMBODIMENTS

An aspect of the present invention is to provide a clock output apparatus having a phase detection and calibration mechanism to determine whether a pair of output clock signals generated by a clock output circuit have a predetermined phase relation when the clock output circuit returns to a first mode from a second mode by using a phase detection circuit such that a phase calibration process is performed when the output clock signals do not have the predetermined phase relation to allow the clock output circuit to restore the predetermined phase relation of the output clock signals.

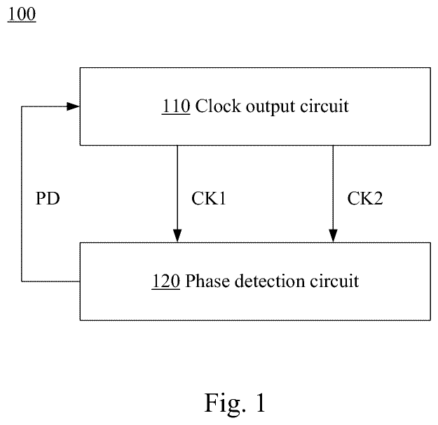

Reference is now made to FIG. 1. FIG. 1 illustrates a circuit diagram of a clock output apparatus 100 having a phase detection and calibration mechanism according to an embodiment of the present invention. The clock output apparatus 100 includes a clock output circuit 110 and a phase detection circuit 120.

The clock output circuit 110 is configured to operate in a first mode and a second mode in turn to generate a pair of output clock signals, wherein the output clock signals include a first output clock signal CK1 and a second output clock signal CK2. The first output clock signal CK1 and the second output clock signal CK2 have a predetermined phase relation in the first mode.

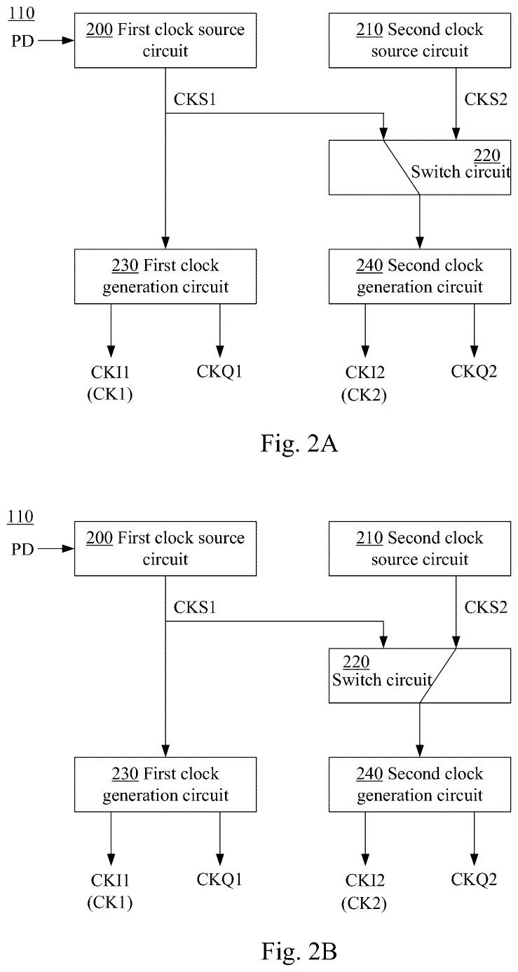

Reference is now made to FIG. 2A and FIG. 2B at the same time. FIG. 2A and FIG. 2B illustrate block diagrams of the clock output circuit 110 according to an embodiment of the present invention. The clock output circuit 110 includes a first clock source circuit 200, a second clock source circuit 210, a switch circuit 220, a first clock generation circuit 230 and a second clock generation circuit 240.

The first clock source circuit 200 is configured to generate a first source clock signal CKS1. The second clock source circuit 210 is configured to generate a second source clock signal CKS2.

The first clock generation circuit 230 is configured to receive the first source clock signal CKS1 to generate a first in-phase clock signal CKI1 and a first quadrature clock signal CKQ1 according to the first source clock signal CKS1 in the first mode and in the second mode.

The second clock generation circuit 240 is configured to selectively electrically coupled to one of the first clock source circuit 200 and the second clock source circuit 210 through the switch circuit 220. The second clock generation circuit 240 receives the second source clock signal CKS2 through the switch circuit 220 and generates a second in-phase clock signal CKI2 and a second quadrature clock signal CKQ2 according to the second source clock signal CKS2 in a first one of the first mode and the second mode. The second clock generation circuit 240 receives the first source clock signal CKS1 through the switch circuit 220 and generates the second in-phase clock signal CKI2 and the second quadrature clock signal CKQ2 according to the first source clock signal CKS1 in a second one of the first mode and the second mode.

In an embodiment, the first one of the first mode and the second mode is the second mode and the second one of the first mode and the second mode is the first mode.

More specifically, in the first mode, the second clock generation circuit 240 receives the first source clock signal CKS1 through the switch circuit 220 to generate the second in-phase clock signal CKI2 and the second quadrature clock signal CKQ2 according to the first source clock signal CKS1, as illustrated in FIG. 2A. In the second mode, the second clock generation circuit 240 receives the second source clock signal CKS2 through the switch circuit 220 to generate the second in-phase clock signal CKI2 and the second quadrature clock signal CKQ2 according to the second source clock signal CKS2, as illustrated in FIG. 2B.

In an embodiment, the pair of output clock signals in FIG. 1 can either be the first in-phase clock signal CKI1 and the second in-phase clock signal CKI2 or be the first quadrature clock signal CKQ1 and the second quadrature clock signal CKQ2. The condition that the first output clock signal CK1 and the second output clock signal CK2 of the pair of output clock signals are respectively the first in-phase clock signal CKI1 and the second in-phase clock signal CKI2 is used as an example to describe the operation of the clock output apparatus 100.

The first in-phase clock signal CKI1 and the second in-phase clock signal CKI2 have the predetermined phase relation in the first mode. In an embodiment, the predetermined phase relation is in phase (the phase difference between the first in-phase clock signal CKI1 and the second in-phase clock signal CKI2 is 0 degree). In another embodiment, the predetermined phase relation is out of phase (the phase difference between the first in-phase clock signal CKI1 and the second in-phase clock signal CKI2 is 180 degrees).

The clock output circuit 110 may in turn operate in the first mode first, switch to operate in the second mode and switch again to return to the first mode. When the clock output circuit 110 returns to the first mode from the second mode, the switch circuit 220 may switch the second clock generation circuit 240 from being electrically coupled to the second clock source circuit 210 (the second mode) to being electrically coupled to the first clock source circuit 200 (the first mode). Under such a condition, since the clock signals received by the second clock generation circuit 240 are not continuous, the predetermined phase relation in the first mode may not be maintained since the second clock generation circuit 240 needs to lock the clock signal received in the first mode again.

As a result, the phase detection circuit 120 may perform a phase detection on the pair of output clock signals, i.e., the first in-phase clock signal CKI1 and the second in-phase clock signal CKI2, to determine whether the pair of output clock signals still have the predetermined phase relation when the clock output circuit 110 returns to the first mode from the second mode.

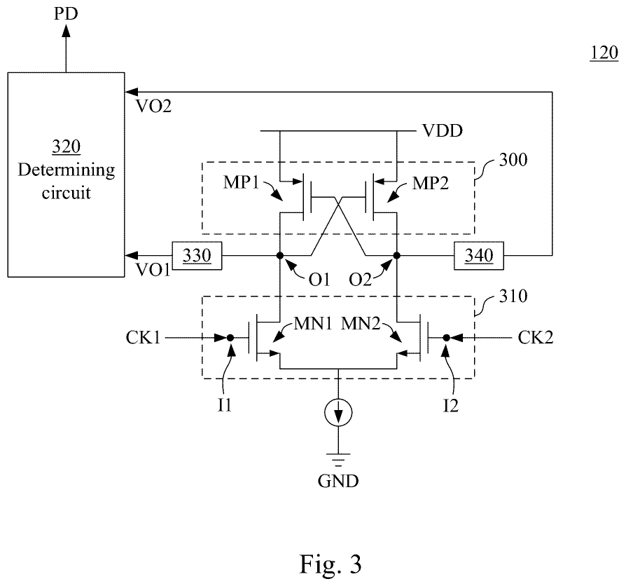

Reference is now made to FIG. 3. FIG. 3 illustrates a block diagram of the phase detection circuit 120 according to an embodiment of the present invention.

The phase detection circuit 120 includes a cross-coupled pair circuit 300, a differential input pair circuit 310 and a determining circuit 320.

The cross-coupled pair circuit 300 is electrically coupled between a power voltage VDD and two output terminals. In the present embodiment, the cross-coupled pair circuit 300 includes a first P-type transistor MP1 and a second P-type transistor MP2.

The first P-type transistor MP1 is electrically coupled between the power voltage VDD and a first output terminal O1 of the two output terminals and has a first P-type transistor gate electrically coupled to a second output terminal O2 of the two output terminals. The second P-type transistor MP2 is electrically coupled between the power voltage VDD and the second output terminal O2 of the two output terminals and has a second P-type transistor gate electrically coupled to the first output terminal O1.

The differential input pair circuit 310 is electrically coupled between the two output terminals and the ground voltage GND and has two input terminals configured to receive the pair of output clock signals. In the present embodiment, the differential input pair circuit 310 includes a first N-type transistor MN1 and a second N-type transistor MN2.

The first N-type transistor MN1 is electrically coupled between the first output terminal O1 and a ground voltage GND and has a first N-type transistor gate serving as a first input terminal I1 of the two input terminals to receive the first output clock signal CK1 of the pair of output clock signals. The second N-type transistor MN2 is electrically coupled between the second output terminal O2 and the ground voltage GND and has a second N-type transistor gate serving as a second input terminal 12 of the two input terminals to receive the second output clock signal CK2 of the pair of output clock signals.

The cross-coupled pair circuit 300 and the differential input pair circuit 310 operate together to generate two output signals at the two output terminals and the output signals include a first output signal VO1 corresponding to the first output terminal O1 and a second output signal VO2 corresponding to the second output terminal O2.

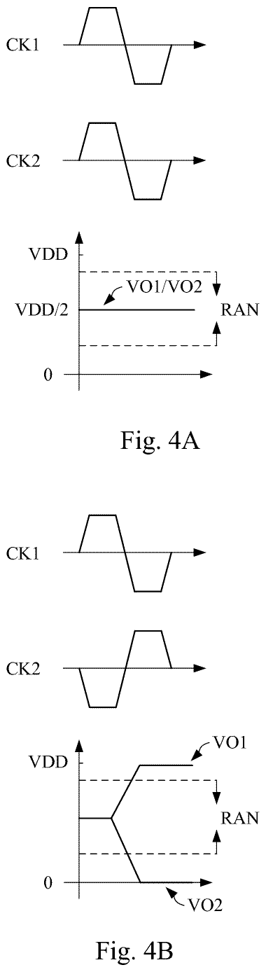

Reference is now made to FIG. 4A and FIG. 4B at the same time. FIG. 4A and FIG. 4B waveform diagrams of the first output clock signal CK1, the second output clock signal CK2, the first output signal VO1 and the second output signal VO2 according to an embodiment of the present invention.

The differential input pair circuit 310 does not amplify the signals having the same level. As a result, as illustrated in FIG. 4A, when the first output clock signal CK1 and the second output clock signal CK2 that are in phase are fed to the first input terminal I1 and the second input terminal 12, the first output clock signal CK1 and the second output clock signal CK2 having the same level make the differential input pair circuit 310 generate the first output signal VO1 and the second output signal VO2 at the first output terminal O1 and the second output terminal O2 each having a level in a predetermined range RAN around a center that is a half of the power voltage VDD, i.e., VDD/2.

The differential input pair circuit 310 amplifies signals having different levels. As a result, as illustrated in FIG. 4B, when the first output clock signal CK1 and the second output clock signal CK2 that are out of phase are fed to the first input terminal I1 and the second input terminal 12, the first output clock signal CK1 and the second output clock signal CK2 having different levels make the differential input pair circuit 310 generate the first output signal VO1 and the second output signal VO2 at the first output terminal O1 and the second output terminal O2 each having the level that is not in the predetermined range RAN around the center that is the half of the power voltage VDD, i.e., VDD/2.

It is appreciated that in FIG. 4B, the condition that the second output clock signal CK2 is the high state and the first output clock signal CK1 is the low state such that the level of the first output signal VO1 is the level of the power voltage VDD and the level of the second output signal VO2 is the level of the ground voltage GND is illustrated. When the first output clock signal CK1 is the low state and the second output clock signal CK2 is the high state, the levels of the first output signal VO1 and the second output signal VO2 are inversed such that the level of the second output signal VO2 is the level of the power voltage VDD and the level of the first output signal VO1 is the level of the ground voltage GND.

The determining circuit 320 is configured to receive at least one of the two output signals from the two output terminals to generate a phase determining result PD.

In an embodiment, the phase detection circuit 120 may selectively include a low-pass filter circuit 330 and a low-pass filter circuit 340 such that the determining circuit 320 receives the first output signal VO1 from the first output terminal O1 through the low-pass filter circuit 330 and receives the second output signal VO2 from the second output terminal O2 through the low-pass filter circuit 340. It is appreciated that the determining circuit 320 may selectively only receive at least one of the two output signals to operate accordingly, the phase detection circuit 120 may only include one of the low-pass filter circuit 330 and the low-pass filter circuit 340 such that the determining circuit 320 correspondingly receives one of the first output signal VO1 and the second output signal VO2.

The determining circuit 320 may obtain the predetermined phase relation by performing detection on the state of the first output signal VO1 and/or the second output signal VO2 in the first mode and may further perform detection on the state of the first output signal VO1 and/or the second output signal VO2 when the clock output circuit 110 returns to the first mode from the second mode to determine whether the detection results of both times are the same to output the phase determining result PD.

For example, when the detection results of both times are the same, the first output signal VO1 and the second output signal VO2 still have the predetermined phase relation when the clock output circuit 110 returns to the first mode from the second mode. The determining circuit 320 generates the phase determining result PD having a first state (e.g., a low state) accordingly. When the detection results of the two times are different, the first output signal VO1 and the second output signal VO2 do not have the predetermined phase relation when the clock output circuit 110 returns to the first mode from the second mode. The determining circuit 320 generates the phase determining result PD having a second state (e.g., a high state) accordingly.

In an example, when the predetermined phase relation is in phase, the determining circuit 320 may detect the first output signal VO1 and/or the second output signal VO2 in the predetermined range RAN in the original first mode. When the determining circuit 320 still detects the first output signal VO1 and/or the second output signal VO2 in the predetermined range RAN under the condition that the clock output circuit 110 returns to the first mode from the second mode, the determining circuit 320 outputs the phase determining result PD having the first state. When the determining circuit 320 detects the first output signal VO1 and/or the second output signal VO2 not in the predetermined range RAN under the condition that the clock output circuit 110 returns to the first mode from the second mode, the determining circuit 320 outputs the phase determining result PD having the second state.

When the predetermined phase relation is out of phase, the determining circuit 320 may detect the first output signal VO1 and/or the second output signal VO2 not in the predetermined range RAN in the original first mode. When the determining circuit 320 still detects the first output signal VO1 and/or the second output signal VO2 not in the predetermined range RAN under the condition that the clock output circuit 110 returns to the first mode from the second mode, the determining circuit 320 outputs the phase determining result PD having the first state. When the determining circuit 320 detects the first output signal VO1 and/or the second output signal VO2 in the predetermined range RAN under the condition that the clock output circuit 110 returns to the first mode from the second mode, the determining circuit 320 outputs the phase determining result PD having the second state.

Based on the above description, the possible values of the phase determining result PD generated by the determining circuit 320 are illustrated in Table 1.

TABLE 1

| Original first mode | Returned first mode | Phase determining result |
|---|---|---|
| In the predetermined | Not in the | First state (having the |
| range | predetermined | predetermined phase |
| | range | relation) |
| In the predetermined | Not in the | Second state (not having |
| range | predetermined | the predetermined phase |
| | range | relation) |
| Not in the predetermined | In the | Second state (not having |
| range | predetermined | the predetermined phase |
| | range | relation) |
| Not in the predetermined | In the | First state (having the |
| range | predetermined | predetermined phase |
| | range | relation) |

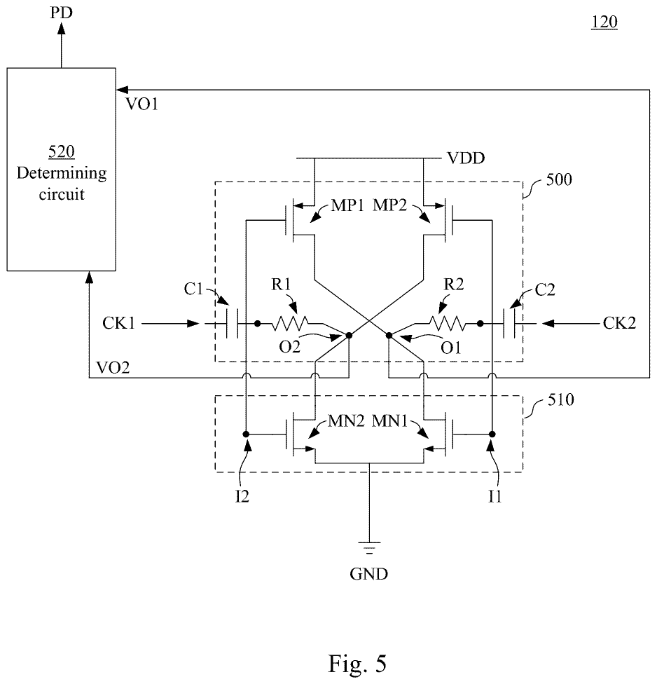

Reference is now made to FIG. 5. FIG. 5 illustrates a block diagram of the phase detection circuit 120 according to another embodiment of the present invention.

The phase detection circuit 120 includes a cross-coupled pair circuit 500, a differential input pair circuit 510 and a determining circuit 520.

The cross-coupled pair circuit 500 is electrically coupled between the power voltage VDD and the two output terminals. In the present embodiment, the cross-coupled pair circuit 500 includes a first resistor R1, a second resistor R2, a first capacitor C1, a second capacitor C2, the first P-type transistor MP1 and the second P-type transistor MP2.

The first P-type transistor MP1 is electrically coupled between the power voltage VDD and the first output terminal O1 of the two output terminals and has the first P-type transistor gate electrically coupled to the second output terminal O2 of the two output terminals through the first resistor R1. The first P-type transistor gate receives the first output clock signal CK1 of the pair of output clock signals through the first capacitor C1. The second P-type transistor MP2 is electrically coupled between the power voltage VDD and the second output terminal O2 of the two output terminals and has the second P-type transistor gate electrically coupled to the first output terminal O1 through second resistor R2. The second P-type transistor gate receives the second output clock signal CK2 of the pair of output clock signals through the second capacitor C2.

The differential input pair circuit 510 is electrically coupled between the two output terminals and the ground voltage GND and has two input terminals configured to receive the pair of output clock signals. In the present embodiment, the differential input pair circuit 510 includes the first N-type transistor MN1 and the second N-type transistor MN2.

The first N-type transistor MN1 is electrically coupled between the first output terminal O1 and the ground voltage GND and has the first N-type transistor gate serving as the first input terminal I1 of the two input terminals to receive the second output clock signal CK2 of the pair of output clock signals through the second capacitor C2. The second N-type transistor MN2 is electrically coupled between the second output terminal O2 and the ground voltage GND and has the second N-type transistor gate serving as the second input terminal 12 of the two input terminals to receive the first output clock signal CK1 of the pair of output clock signals through the first capacitor C1.

The cross-coupled pair circuit 500 and the differential input pair circuit 510 operate together to generate two output signals at the two output terminals and the output signals include the first output signal VO1 corresponding to the first output terminal O1 and the second output signal VO2 corresponding to the second output terminal O2.

Similar to the phase detection circuit 120 in FIG. 3, the differential input pair circuit 510 does not amplify the signals having the same level. As a result, as illustrated in FIG. 4A, when the first output clock signal CK1 and the second output clock signal CK2 that are in phase are fed to the first input terminal I1 and the second input terminal 12, the first output clock signal CK1 and the second output clock signal CK2 having the same level make the differential input pair circuit 510 generate the first output signal VO1 and the second output signal VO2 at the first output terminal O1 and the second output terminal O2 each having a level in the predetermined range RAN around the center that is the half of the power voltage VDD, i.e., VDD/2.

Further, the differential input pair circuit 510 amplifies signals having different levels. As a result, as illustrated in FIG. 4B, when the first output clock signal CK1 and the second output clock signal CK2 that are out of phase are fed to the first input terminal I1 and the second input terminal 12, the first output clock signal CK1 and the second output clock signal CK2 having different levels make the differential input pair circuit 310 generate the first output signal VO1 and the second output signal VO2 at the first output terminal O1 and the second output terminal O2 each having the level that is not in the predetermined range RAN around the center that is the half of the power voltage VDD, i.e., VDD/2. The details are not described herein.

The operation mechanism of the determining circuit 520 to generate the phase determining result PD is the same as that of the determining circuit 320 in FIG. 3. The details are not described herein.

Based on the detection mechanism of the phase detection circuit 120 in FIG. 3 or FIG. 5 described above, a phase calibration process can be performed when the clock output circuit 110 returns to the first mode from the second mode and when the phase determining result PD indicates that the pair of output clock signals do not have the predetermined phase relation such that the predetermined phase relation of the pair of output clock signals can be restored.

In the embodiment that the configuration of the clock output circuit 110 in FIG. 2A corresponds to the first mode and the configuration of the clock output circuit 110 in FIG. 2B corresponds to the second mode, the clock output circuit 110 may receive the phase determining result PD by the first clock source circuit 200 to be reset to perform the phase calibration process when the clock output circuit 110 returns to the first mode from the second mode and when the phase determining result PD indicates that the pair of output clock signals do not have the predetermined phase relation.

However, in another embodiment, when the first one of the first mode and the second mode is the first mode and the second one of the first mode and the second mode is the second mode, the configuration of the clock output circuit 110 in FIG. 2B corresponds to the first mode and the configuration of the clock output circuit 110 in FIG. 2A corresponds to the second mode. Under such a condition, the clock output circuit 110 may receive the phase determining result PD by the second clock source circuit 210 to be reset to perform the phase calibration process when the clock output circuit 110 returns to the first mode from the second mode and when the phase determining result PD indicates that the pair of output clock signals do not have the predetermined phase relation.

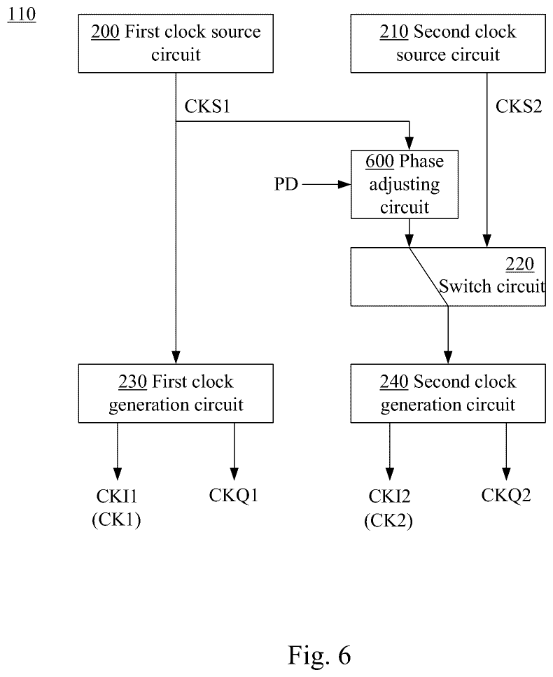

Reference is now made to FIG. 6. FIG. 6 illustrates a block diagram of the clock output circuit 110 according to another embodiment of the present invention. Similar to FIG. 2A and FIG. 2B, the clock output circuit 110 in FIG. 6 includes the first clock source circuit 200, the second clock source circuit 210, the switch circuit 220, the first clock generation circuit 230 and the second clock generation circuit 240. The operation of these circuits is identical to that described in the embodiment in FIG. 2A and FIG. 2B and is not described herein.

In the embodiment of FIG. 6, the clock output circuit 110 further includes a phase adjusting circuit 600. In response to the condition that the first one of the first mode and the second mode is the second mode, the phase adjusting circuit 600 is disposed between the first clock source circuit 200 and the switch circuit 220, as illustrated in FIG. 6, to receive the phase determining result PD to perform a phase adjusting on the first source clock signal CKS1 to perform the phase calibration process when the clock output circuit 110 returns to the first mode from the second mode and when the phase determining result PD indicates that the pair of output clock signals do not have the predetermined phase relation.

In another embodiment, in response to the condition that the first one of the first mode and the second mode is the first mode, the phase adjusting circuit 600 is disposed between the second clock source circuit 210 and the switch circuit 220 (not illustrated in the figure) to receive the phase determining result PD to perform a phase adjusting on the second source clock signal CKS2 to perform the phase calibration process when the clock output circuit 110 returns to the first mode from the second mode and when the phase determining result PD indicates that the pair of output clock signals do not have the predetermined phase relation.

By using the operation described above, the clock output apparatus 100 may determine whether the output clock signals generated by the clock output circuit 110 have the predetermined phase relation when the clock output circuit 110 returns to the first mode from the second mode such that in response to the condition that the output clock signals do not have the predetermined phase relation, the phase calibration process is performed by using the phase detection circuit 120 such that the clock output circuit 110 restores the predetermined phase relation of the output clock signals.

In a usage scenario, the first in-phase clock signal CKI1 and the first quadrature clock signal CKQ1 generated by the clock output circuit 110 are outputted to a first receiver circuit (represented by RX1) in a communication apparatus (not illustrated) such that the first receiver circuit operates according to the first in-phase clock signal CKI1 and the first quadrature clock signal CKQ1. The second in-phase clock signal CKI2 and the second quadrature clock signal CKQ2 generated by the clock output circuit 110 are outputted to a second receiver circuit (represented by RX2) in the communication apparatus such that the second receiver circuit operates according to the second in-phase clock signal CKI2 and the second quadrature clock signal CKQ2. Under such a condition, the clock output apparatus 100 allow different receiver circuits to perform signal receiving according to the correct phase relations by using the phase detection mechanism and the phase calibration mechanism described above to increase the accuracy of the signal receiving.

It is appreciated that the embodiments described above are merely an example. In other embodiments, it should be appreciated that many modifications and changes may be made by those of ordinary skill in the art without departing, from the spirit of the disclosure.

For example, in the embodiments described above, the condition that the switch circuit 220 is disposed corresponding to the second clock generation circuit 240 such that the second clock generation circuit 240 receives the first source clock signal CKS1 or the second source clock signal CKS2 in different modes and the first clock generation circuit 230 only receives the first source clock signal CKS1 without any switching is used as an example.

In another embodiment, the switch circuit 220 may be disposed corresponding to the first clock generation circuit 230 such that the first clock generation circuit 230 receives the first source clock signal CKS1 or the second source clock signal CKS2 in different modes and the second clock generation circuit 240 only receives the second source clock signal CKS2 without any switching. In yet another embodiment, the switch circuit 220 may be disposed corresponding to both of the first clock generation circuit 230 and the second clock generation circuit 240 such that both the first clock generation circuit 230 and the second clock generation circuit 240 can switch to receive the first source clock signal CKS1 or the second source clock signal CKS2. The present invention is not limited thereto.

Besides, in the embodiments described above, the predetermined phase relation is either in phase or out of phase. In other embodiments, the predetermined phase relation can be other phase differences. For example, when the predetermined phase relation is a phase difference of 90 degrees, the first output clock signal CK1 and the second output clock signal CK2 are in turn in the states of in phase and out of phase in an interlaced manner such that the cross-coupled pair circuit 300 and the differential input pair circuit 310 that operate together generate the first output signal VO1 and the second output signal VO2 each having a level in turn in the predetermined range RAN and out of the predetermined range RAN in an interlaced manner. The determining circuit 320 may determine whether at least one of the first output signal VO1 and the second output signal VO2 matches the pattern described above to generate the phase determining result PD. The present invention is not limited thereto.

Further, in the embodiments described above, the condition that the first output clock signal CK1 and the second output clock signal CK2 of the pair of output clock signals are the first in-phase clock signal CKI1 and the second in-phase clock signal CKI2 is used as an example. In other embodiments, the first output clock signal CK1 and the second output clock signal CK2 can be the first quadrature clock signal CKQ1 and the second quadrature clock signal CKQ2 for the phase detection circuit 120 to perform detection. The present invention is not limited thereto.

In summary, the present invention discloses the clock output apparatus having a phase detection and calibration mechanism that determines whether a pair of output clock signals generated by a clock output circuit have a predetermined phase relation when the clock output circuit returns to a first mode from a second mode by using a phase detection circuit such that a phase calibration process is performed when the output clock signals do not have the predetermined phase relation to allow the clock output circuit to restore the predetermined phase relation of the output clock signals.

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. A clock output apparatus having a phase detection and calibration mechanism, comprising:
a clock output circuit configured to operate in a first mode and a second mode in turn to generate a pair of output clock signals, wherein the pair of output clock signals have a predetermined phase relation in the first mode; and
a phase detection circuit comprising:
a cross-coupled pair circuit electrically coupled between a power voltage and two output terminals;
a differential input pair circuit;
a determining circuit electrically coupled between the two output terminals and a ground voltage and having two input terminals configured to receive the pair of output clock signals, wherein the cross-coupled pair circuit and the differential input pair circuit operate together to generate two output signals at the two output terminals each having a level in a predetermined range around a center that is a half of the power voltage when the output clock signals are in phase and generate the two output signals at the two output terminals each having the level that is not in the predetermined range when the output clock signals are out of phase; and
a determining circuit configured to receive at least one of the two output signals from the two output terminals to generate a phase determining result;
wherein the clock output circuit performs a phase calibration process when the clock output circuit returns to the first mode from the second mode and the phase determining result indicates that the pair of output clock signals do not have the predetermined phase relation, so as to control the pair of output clock signals to have the predetermined phase relation.

2. The clock output apparatus of claim 1, wherein the cross-coupled pair circuit comprises:
a first P-type transistor electrically coupled between the power voltage and a first output terminal of the two output terminals and having a first P-type transistor gate electrically coupled to a second output terminal of the two output terminals; and
a second P-type transistor electrically coupled between the power voltage and the second output terminal and having a second P-type transistor gate electrically coupled to the first output terminal.

3. The clock output apparatus of claim 2, wherein the differential input pair circuit comprises:
a first N-type transistor electrically coupled between the first output terminal and the ground voltage and having a first N-type transistor gate serving as a first input terminal of the two input terminals to receive a first output clock signal of the pair of output clock signals; and
a second N-type transistor configured to electrically coupled between the second output terminal and the ground voltage and having a second N-type transistor gate serving as a second input terminal of the two input terminals to receive a second output clock signal of the pair of output clock signals.

4. The clock output apparatus of claim 2, wherein the phase detection circuit further comprises a low-pass filter circuit such that the determining circuit receives at least one of the two output signals from the two output terminals through the low-pass filter circuit.

5. The clock output apparatus of claim 1, wherein the cross-coupled pair circuit comprises:
a first resistor and a second resistor;
a first capacitor and a second capacitor;
a first P-type transistor electrically coupled between the power voltage and a first output terminal of the two output terminals and having a first P-type transistor gate electrically coupled to a second output terminal of the two output terminals through the first resistor; and
a second P-type transistor electrically coupled between the power voltage and the second output terminal and having a second P-type transistor gate electrically coupled to the first output terminal through the second resistor;
wherein the first P-type transistor gate receives a first output clock signal of the pair of output clock signals through the first capacitor and the second P-type transistor gate receives a second output clock signal of the pair of output clock signals through the second capacitor.

6. The clock output apparatus of claim 5, wherein the differential input pair circuit comprises:
a first N-type transistor electrically coupled between the first output terminal and the ground voltage and having a first N-type transistor gate serving as a first input terminal of the two input terminals to receive the second output clock signal through the second capacitor; and
a second N-type transistor electrically coupled between the second output terminal and the ground voltage and having a second N-type transistor gate serving as a second input terminal of the two input terminals to receive the first output clock signal through the first capacitor.

7. The clock output apparatus of claim 1, wherein the clock output circuit comprises:
a first clock source circuit configured to generate a first source clock signal;
a second clock source circuit configured to generate a second source clock signal;
a switch circuit;
a first clock generation circuit configured to receive the first source clock signal to generate a first in-phase clock signal and a first quadrature clock signal according to the first source clock signal in the first mode and in the second mode; and
a second clock generation circuit configured to selectively electrically coupled to one of the first clock source circuit and the second clock source circuit through the switch circuit, wherein the second clock generation circuit receives the second source clock signal through the switch circuit and generates a second in-phase clock signal and a second quadrature clock signal according to the second source clock signal in a first one of the first mode and the second mode, and the second clock generation circuit receives the first source clock signal through the switch circuit and generates the second in-phase clock signal and the second quadrature clock signal according to the first source clock signal in a second one of the first mode and the second mode;
wherein the pair of output clock signals are either the first in-phase clock signal and the second in-phase clock signal or the first quadrature clock signal and the second quadrature clock signal.

8. The clock output apparatus of claim 7, wherein in response to the condition that the first one of the first mode and the second mode is the second mode, the first clock source circuit receives the phase determining result to be reset to perform the phase calibration process when the clock output circuit returns to the first mode from the second mode and when the phase determining result indicates that the pair of output clock signals do not have the predetermined phase relation; and
in response to the condition that the first one of the first mode and the second mode is the first mode, the second clock source circuit receives the phase determining result to be reset to perform the phase calibration process when the clock output circuit returns to the first mode from the second mode and when the phase determining result indicates that the pair of output clock signals do not have the predetermined phase relation.

9. The clock output apparatus of claim 7, wherein the clock output circuit further comprises a phase adjusting circuit;
in response to the condition that the first one of the first mode and the second mode is the second mode, the phase adjusting circuit is disposed between the first clock source circuit and the switch circuit to receive the phase determining result to perform a phase adjusting on the first source clock signal to perform the phase calibration process when the clock output circuit returns to the first mode from the second mode and when the phase determining result indicates that the pair of output clock signals do not have the predetermined phase relation; and
in response to the condition that the first one of the first mode and the second mode is the first mode, the phase adjusting circuit is disposed between the second clock source circuit and the switch circuit to receive the phase determining result to perform the phase adjusting on the second source clock signal to perform the phase calibration process when the clock output circuit returns to the first mode from the second mode and when the phase determining result indicates that the pair of output clock signals do not have the predetermined phase relation.

10. The clock output apparatus of claim 7, wherein the first in-phase clock signal and the first quadrature clock signal are outputted to a first receiver circuit of a communication apparatus such that the first receiver circuit operates according to the first in-phase clock signal and the first quadrature clock signal; and
the second in-phase clock signal and the second quadrature clock signal are outputted to a second receiver circuit of the communication apparatus such that the second receiver circuit operates according to the second in-phase clock signal and the second quadrature clock signal.
